(19) United States
(12) Patent Application Publication
(10) Pub. No.: US 2026/0247630 A1
(43) Pub. Date: Aug. 20, 2026

(54) MEMORY ARCHITECTURE AND ASSEMBLY PROCESS FOR SEMICONDUCTOR DEVICES

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 19/055,376

(22) Filed: Feb. 17, 2025

(51) Int. Cl. H10B 80/00; H01L 23/00; H01L 25/00; H01L 25/065; H01L 25/18

(52) U.S. Cl. CPC H10B 80/00; H10W 90/00; H10W 80/211; H10W 80/312; H10W 80/327; H10W 90/792

(57) ABSTRACT

A structure is disclosed. The structure can include a logic chip, a first conductor, and a plurality of memory dies. The logic chip can be configured to access the plurality of memory dies. Each of the plurality of memory dies can be electrically connected to the logic chip at least through the first conductor. Each of the plurality of memory dies can include a top major surface, a bottom major surface that is parallel to the top major surface, and a minor surface non-parallel to the top major surface and the bottom major surface. Each of the plurality of memory dies can be bonded to the logic chip through the minor surface, where the minor surface comprises artifacts indicative of at least a singulation process applied on a memory die.

### BACKGROUND

### Field

This disclosure relates to semiconductor device structures and methods. In particular, some embodiments are directed to memory architectures and configurations.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As the demand for higher storage capacity and performance grows, memory structures or architectures such as High Bandwidth Memory (HBM) and Dynamic Random-Access Memory (DRAM) stacks have become increasingly complex. It can be challenging to manage yield, thermal dissipation, assembly, and/or interconnect real estate associated with semiconductor packages that include memory stacks. It may be desirable to find new memory architectures for semiconductor devices.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a memory architecture including memory dies and a logic chip.

FIG. 1B illustrates an example layout of memory channels in the memory architecture of FIG. 1A.

FIG. 2A illustrates a perspective view of a portion of a bonded structure for implementing the memory architecture of FIG. 1A.

FIG. 2B illustrates a perspective view of a portion of the bonded structure for implementing the memory architecture of FIG. 1A.

FIG. 2C illustrates a perspective view of a portion of the bonded structure for implementing the memory architecture of FIG. 1A.

FIG. 2D illustrates a perspective view of a portion of the bonded structure for implementing the memory architecture of FIG. 1A.

FIG. 2E illustrates a diagram of a stacked memory structure including two groups of memory dies stacked above a logic chip.

FIG. 2F illustrates a diagram of a stacked memory structure including three groups of memory dies stacked above a logic chip.

FIG. 3 illustrates a perspective view of an example stacked memory structure including high bandwidth memory dies to be singulated along a direction for implementing the memory architecture of FIG. 1A according to some embodiments.

FIG. 4A illustrates a perspective view of an example bonded structure obtained from singulating, orienting, and/or bonding high bandwidth memory dies of the bonded structure of FIG. 3 to a logic chip according to some embodiments.

FIG. 4B illustrates a perspective view of an example bonded structure obtained from singulating, orienting, and/or bonding high bandwidth memory dies of the bonded structure of FIG. 3 to a logic chip according to some embodiments.

FIG. 5 illustrates a perspective view of an example stacked memory structure including high bandwidth memory dies to be singulated along another direction for implementing the memory architecture of FIG. 1A according to some embodiments.

FIG. 6A illustrates a perspective view of an example bonded structure obtained from singulating, orienting, and/or bonding high bandwidth memory dies of the bonded structure of FIG. 5 to a logic chip according to some embodiments.

FIG. 6B illustrates a perspective view of an example bonded structure obtained from singulating, orienting, and/or bonding high bandwidth memory dies of the bonded structure of FIG. 5 to a logic chip according to some embodiments.

FIGS. 7A and 7B schematically illustrate cross-sectional side views of two elements prior to and after, respectively, a process for forming a directly bonded structure, and more particularly a hybrid bonded structure, according to some embodiments.

### SUMMARY

The systems, methods, and devices described herein each have several aspects, no single one of which is solely responsible for its desirable attributes. Without limiting the scope of this disclosure, several non-limiting features will now be described briefly.

In some aspects, the techniques described herein relate to a structure including: a logic chip configured to access at least a first plurality of memory dies; a first conductor; and the first plurality of memory dies, each of the first plurality of memory dies electrically connected to the logic chip at least through the first conductor, wherein each of the first plurality of memory dies includes a first top major surface, a first bottom major surface that is parallel to the first top major surface, and a first top minor surface and a first bottom minor surface non-parallel to the first top major surface and the first bottom major surface, wherein each of the first plurality of memory dies is bonded to the logic chip through the first bottom minor surface, and wherein the first top minor surface includes first artifacts indicative of at least a first singulation process.

In some aspects, the techniques described herein relate to a structure, wherein an area of the first bottom minor surface is smaller than an area of the first top major surface or smaller than an area of the first bottom major surface.

In some aspects, the techniques described herein relate to a structure, wherein the first plurality of memory dies are diced from a first memory die, and wherein the logic chip accesses the first plurality of memory dies through the first conductor as if the first plurality of memory dies were disposed within and not diced from the first memory die.

In some aspects, the techniques described herein relate to a structure, wherein each of the first plurality of memory dies includes a first plurality of memory banks.

In some aspects, the techniques described herein relate to a structure, wherein each of the first plurality of memory banks is electrically connected with each other before and after the first plurality of memory dies are diced from a first memory die.

In some aspects, the techniques described herein relate to a structure, wherein at least one of the first plurality of memory banks is electrically unconnected to another of the first plurality of memory banks before the first plurality of memory dies are diced from a first memory die.

In some aspects, the techniques described herein relate to a structure, wherein each of the first plurality of memory banks is electrically connected to the logic chip through a redistribution layer (RDL), and wherein the first conductor includes a first conductive trace that is routed in the RDL.

In some aspects, the techniques described herein relate to a structure, wherein the first plurality of memory banks includes two, four, or eight memory banks, and wherein the first plurality of memory dies includes four, eight, twelve, or sixteen memory dies.

In some aspects, the techniques described herein relate to a structure, further including: a second conductor; and a second plurality of memory dies, each of the second plurality of memory dies electrically connected to the logic chip at least through the second conductor, wherein each of the second plurality of memory dies includes a second top major surface, a second bottom major surface that is parallel to the second top major surface, and a second top minor surface and a second bottom minor surface non-parallel to the second top major surface and the second bottom major surface, wherein each of the second plurality of memory dies is bonded to the logic chip through the second bottom minor surface, and wherein the second top minor surface includes second artifacts indicative of at least a second dicing or singulation process.

In some aspects, the techniques described herein relate to a structure, wherein a first memory die and a second memory die are stacked vertically before the first plurality of memory dies are diced from the first memory die and the second plurality of memory dies are diced from the second memory die, and wherein the first plurality of memory dies and the second plurality of memory dies are laterally spaced from each other along a surface of the logic chip after the first plurality of memory dies and the second plurality of memory dies are bonded to the logic chip.

In some aspects, the techniques described herein relate to a structure, further including: a third conductor; and a third plurality of memory dies, each of the third plurality of memory dies electrically connected to the logic chip at least through the third conductor, wherein each of the third plurality of memory dies includes a third top major surface, a third bottom major surface that is parallel to the third top major surface, and a third top minor surface and a third bottom minor surface non-parallel to the third top major surface and the third bottom major surface, wherein each of the third plurality of memory dies is bonded to the logic chip through the third bottom minor surface, and wherein the third top minor surface includes third artifacts indicative of at least a third dicing or singulation process.

In some aspects, the techniques described herein relate to a structure, further including: a fourth conductor; and a fourth plurality of memory dies, each of the fourth plurality of memory dies electrically connected to the logic chip at least through the fourth conductor, wherein each of the fourth plurality of memory dies includes a fourth top major surface, a fourth bottom major surface that is parallel to the fourth top major surface, and a fourth top minor surface and a fourth bottom minor surface non-parallel to the fourth top major surface and the fourth bottom major surface, wherein each of the fourth plurality of memory dies is bonded to the logic chip through the fourth bottom minor surface, and wherein the fourth top minor surface includes fourth artifacts indicative of at least a fourth dicing or singulation process.

In some aspects, the techniques described herein relate to a structure, wherein the first conductor includes a first conductive trace that is routed across the first top major surface and the first bottom major surface.

In some aspects, the techniques described herein relate to a structure, wherein the first plurality of memory dies are diced from a first memory die, and wherein the first plurality of memory dies are laterally spaced from each other by at least another memory die that is not diced from the first memory die.

In some aspects, the techniques described herein relate to a structure, wherein the first plurality of memory dies are diced from a first memory die, and wherein the first plurality of memory dies are adjacent to each other without another memory die that is not diced from the first memory die in between.

In some aspects, the techniques described herein relate to a structure, wherein one of the first plurality of memory dies is hybrid bonded to another of the first plurality of memory dies.

In some aspects, the techniques described herein relate to a structure, wherein one of the first plurality of memory dies is bonded to another of the first plurality of memory dies through adhesive.

In some aspects, the techniques described herein relate to a structure, wherein the first conductor includes a first conductive trace that is routed along the first bottom minor surface rather than across the first top major surface and the first bottom major surface.

In some aspects, the techniques described herein relate to a structure, wherein the first conductor includes a first conductive trace that is routed in a redistribution layer (RDL) of the logic chip.

In some aspects, the techniques described herein relate to a structure, wherein the first conductor includes a first conductive trace that is routed in a redistribution layer (RDL) of the first plurality of memory dies.

In some aspects, the techniques described herein relate to a structure, wherein each of the first plurality of memory dies is hybrid bonded to the logic chip through the first bottom minor surface.

In some aspects, the techniques described herein relate to a structure, wherein each of the first plurality of memory dies is bonded to the logic chip through the first bottom minor surface using adhesive.

In some aspects, the techniques described herein relate to a structure, wherein the first plurality of memory dies are reconstituted before bonded to the logic chip.

In some aspects, the techniques described herein relate to a structure, wherein the first plurality of memory dies are flipped by ninety degrees before bonded to the logic chip.

In some aspects, the techniques described herein relate to a method for forming a bonded structure, the method including: forming at least (i) first memory banks in a first memory die and (ii) second memory banks in a second memory die; stacking at least the first memory die and the second memory die vertically to form a memory die stack; dicing the memory die stack to form at least (i) a first plurality of memory dies from the first memory die and (ii) a second plurality of memory dies from the second memory die; and bonding the first plurality of memory dies and the second plurality of memory dies to a logic chip, wherein each of the first plurality of memory dies includes a first plurality of memory banks that correspond to a subset of the first memory banks and each of the second plurality of memory dies includes a second plurality of memory banks that correspond to a subset of the second memory banks.

In some aspects, the techniques described herein relate to a method, further including: orienting the first plurality of memory dies and the second plurality of memory dies such that the first plurality of memory dies and the second plurality of memory dies are to be perpendicularly bonded to the logic chip.

In some aspects, the techniques described herein relate to a method, wherein bonding the first plurality of memory dies and the second plurality of memory dies includes bonding each of the first plurality of memory dies and each of the second plurality of memory dies to the logic chip using hybrid bonding.

In some aspects, the techniques described herein relate to a method, further including: reconstituting the first plurality of memory dies and the second plurality of memory dies prior to bonding the first plurality of memory dies and the second plurality of memory dies to the logic chip.

In some aspects, the techniques described herein relate to a method, wherein reconstituting the first plurality of memory dies and the second plurality of memory dies includes: forming (i) a first redistribution layer (RDL) in the first plurality of memory dies for electrically connecting the first plurality of memory banks to the logic chip and (ii) a second redistribution layer (RDL) in the second plurality of memory dies for electrically connecting the second plurality of memory banks to the logic chip.

In some aspects, the techniques described herein relate to a method, wherein the first plurality of memory dies and the second plurality of memory dies are carried by a carrier substrate or interposer when being reconstituted.

In some aspects, the techniques described herein relate to a method, further including: removing the carrier substrate after the first plurality of memory dies and the second plurality of memory dies are reconstituted.

In some aspects, the techniques described herein relate to a method, wherein bonding the first plurality of memory dies and the second plurality of memory dies includes bonding each of the first plurality of memory dies and each of the second plurality of memory dies to the logic chip using adhesive.

In some aspects, the techniques described herein relate to a method, wherein bonding the first plurality of memory dies and the second plurality of memory dies includes hybrid bonding each of the first plurality of memory dies and each of the second plurality of memory dies to the logic chip.

In some aspects, the techniques described herein relate to a method, further including: forming a redistribution layer (RDL) on the logic chip for electrically connecting the first plurality of memory banks and the second plurality of memory banks to the logic chip.

In some aspects, the techniques described herein relate to a method, further including: hybrid bonding one of the first plurality of memory dies to another of the first plurality of memory dies.

In some aspects, the techniques described herein relate to a method, further including: bonding one of the first plurality of memory dies to another of the first plurality of memory dies using adhesive.

In some aspects, the techniques described herein relate to a method, further including: forming (i) third memory banks in a third memory die and (ii) fourth memory banks in a fourth memory die; and stacking the third memory die and the fourth memory die vertically into the memory die stack, wherein dicing the memory die stack further forms (i) a third plurality of memory dies from the third memory die and (ii) a fourth plurality of memory dies from the fourth memory die.

In some aspects, the techniques described herein relate to a method, further including: bonding the third plurality of memory dies and the fourth plurality of memory dies to the logic chip.

In some aspects, the techniques described herein relate to a method for forming a bonded structure, the method including: forming first memory banks in a first memory die; dicing the first memory die into a first plurality of memory dies, each of the first plurality of memory dies including a first plurality of memory banks; and bonding the first plurality of memory dies to a logic chip, wherein each of the first plurality of memory dies includes a first plurality of memory banks that correspond to a subset of the first memory banks.

In some aspects, the techniques described herein relate to a method, further including: orienting the first plurality of memory dies such that the first plurality of memory dies are to be bonded to the logic chip through a minor surface of the first plurality of memory dies.

In some aspects, the techniques described herein relate to a method, further including: reconstituting the first plurality of memory dies prior to bonding the first plurality of memory dies to the logic chip.

In some aspects, the techniques described herein relate to a structure including: a logic chip; a first conductor; and a first plurality of integrated circuit dies, each of the first plurality of integrated circuit dies electrically connected to the logic chip at least through the first conductor, wherein each of the first plurality of integrated circuit dies includes a top major surface, a bottom major surface that is parallel to the top major surface, and a minor surface non-parallel to the top major surface and the bottom major surface, wherein each of the first plurality of integrated circuit dies is bonded to the logic chip through the minor surface, and wherein the minor surface includes artifacts indicative of one or more singulation processes.

In some aspects, the techniques described herein relate to a structure, wherein an area of the minor surface is smaller than an area of the top major surface or smaller than an area of the bottom major surface.

In some aspects, the techniques described herein relate to a structure, wherein the first plurality of integrated circuit dies are diced from the first integrated circuit die, and wherein the logic chip communicates with the first plurality of integrated circuit dies through the first conductor as if the first plurality of integrated circuit dies were disposed within and not diced from the first integrated circuit die.

In some aspects, the techniques described herein relate to a structure, wherein the first conductor includes a conductive trace routed in a redistribution layer (RDL).

In some aspects, the techniques described herein relate to a structure, wherein the first plurality of memory dies include high bandwidth memory (HBM).

Various combinations of the above and below recited features, embodiments, and aspects are also disclosed and contemplated by the present disclosure.

Additional embodiments of the disclosure are described below in reference to the appended claims, which may serve as an additional summary of the disclosure.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

In the era of artificial intelligence or high-performance computing, existing structures and approaches for bonding, assembling, or packaging memory dies may face limitations in terms of memory bandwidth and capacity. Some embodiments disclosed herein nevertheless accomplish high bandwidth, high capacity, and/or low latency memory architecture by dicing, orienting, and/or bonding memory dies to other semiconductor dies.

There is increasing demand for higher memory bandwidth and higher memory capacity. Providing high speed and high bandwidth connections between memory dies and other semiconductor dies (e.g., processor dies) can be important for some applications. For example, when training an artificial intelligence or machine learning model, performing complex graphical operations, or carrying out other data-intensive tasks, processors such as central processing units (CPUs), graphical processing units (GPUs), field programmable gate arrays (FPGAs), Neural Processing Units (NPUs), Tensor Processing Units (TPUs), application specific integrated circuits (ASICs), and so forth can spend a significant amount of time idle while waiting for data from memory devices like dynamic random-access memory (DRAM) (e.g., high bandwidth memory (HBM)), storage class memory (e.g. NAND), etc., which can negatively impact performance and increase the time it takes to complete a given or multiple computing tasks.

As used herein, high bandwidth memory (HBM) can refer to a type of dynamic random-access memory (DRAM) that is used in conjunction with high-performance computing systems. HBMs may provide high data transfer rates and low power consumption. HBM can allow for increased memory bandwidth and/or provide interface for memory access in applications or systems that include graphics processing units (GPUs), central processing units (CPUs), artificial intelligence (AI) accelerators, and/or the like. In some examples, a HBM can include a plurality of dies (e.g., a base logic die and multiple DRAM dies stacked upon the base logic die). To meet increasing demand for higher memory bandwidth and/or capacity, HBMs can include memory dies that are stacked on and connected to a controller circuit such as a processor die or a logic chip through some interconnect schemes (e.g., through substrate via or through silicon via (TSV)). For example, in existing semiconductor packages, multiple memory dies may be stacked above a logic chip or a controller chip that accesses the memory dies through TSVs. In some examples, HBM can support a bandwidth of greater than 250 gigabyte (GB) per stack. In some examples, HBM can support a bandwidth of greater than 400 GB per stack. In some examples, HBM can support a bandwidth of greater than 1000 GB per stack. In some examples, a HBM stack can have a memory bus that is wider than a memory bus of double data rate (DDR) or graphics double data rate (GDDR) memory devices, and can increase bandwidth, increase power efficiency, and/or lower memory latency. In some examples, a HBM stack can have a memory bus that has a width of 1024 bits or greater. In some examples, compared with DDR or GDDR memory devices, a HBM stack can operate at lower frequencies and voltages, while achieving higher data throughput. In some examples, a HBM stack can have a power efficient of 5 picojoules (pj) per bit transferred or less. In some examples, a HBM stack can have a power efficient of 4 pj/bit. In some examples, a HBM stack can have a power efficient of 3 pj/bit.

However, as more memory dies are stacked together vertically to provide higher bandwidth or capacity, memory latency associated with a HBM memory stack may increase. For example, it may take more time to transfer data from a memory die stacked toward the top of a memory stack to a logic chip below the memory stack. Data transfer speed may be limited by a length of connecting conductor (e.g., TSVs), which can pose a bottleneck to memory latency. This may also prevent the logic chip from effectively accessing certain HBMs, thereby compromising data transfer efficiency (e.g., reducing memory bandwidth).

Additionally, overall memory capacity of a memory stack may be constrained by a height of the memory stack. Existing semiconductor packages typically stack up to twelve or sixteen memory dies vertically. As such, memory capacity of the memory stack may not go beyond corresponding memory capacity provided by twelve or sixteen memory dies. Limited number of memory dies in a stack can also be due to the stacking process yield. Since stacking can be a cumbersome process, higher number of dies of the stack may reduce the overall yield.

Further, to provide sufficient memory bandwidth for certain applications, area or real estate occupied by interconnect structures may increase. For example, to support high memory bandwidth operations, more TSVs may need to be disposed within HBM memory stacks. These TSVs may occupy considerable space within a memory stack, which may incur significant cost for manufacturing the memory stack and/or packaging the memory stack into semiconductor packages. Further, although electrical signals can be routed (e.g., through one or more TSVs formed within memory dies of a memory stack) from a top memory die to a bottom memory die or a logic chip below the memory stack, additional or increased resistance may be introduced in the route because of presence of TSVs. The increased resistance may degrade electrical characteristic or performance (e.g., more electrical energy wasted due to increased resistance) associated with the memory stack. Increased amount or usage of TSVs and other interconnect structures can also lead to thermal issues associated with the memory stack. For example, long TSVs may impede efficient heat dissipation, leading to hotspots and potential thermal stress across a memory stack. Still, the complexity and cost of manufacturing or assembling a HBM memory stack may increase because of increased use of interconnect structures (e.g., TSVs). This may negatively impact yield and reliability of the HBM memory stack, affecting overall performance of semiconductor devices. Additionally, stacking complicates thermal dissipation issues of the dies. For example, dies located towards the bottom of the stack tend to exhibit higher temperature compared to the dies towards the top of the stack. More specifically, although temperatures of dies toward the bottom and dies toward the top may both increase, a heat spreader (e.g., a cooling device or structure) may be attached at the top of the stack. As such, dies toward the top may have easier access to the heat spreader, but heat may be more likely to be trapped or less effectively dissipated toward the bottom of the stack.

To address at least a portion of the aforementioned problems, some embodiments herein reduce or eliminate the use of certain interconnect components (e.g., TSVs) to electrically connect memory dies and a logic chip by dicing (e.g., through one or more singulation process), orienting, and/or bonding memory dies to a logic chip. As used herein, the logic chip can be a semiconductor die that accesses and/or controls access to the memory dies. For example, the logic chip can manage read and write operations associated with the memory dies, facilitating communications between the memory dies and other semiconductor dies (e.g., processor dies such as CPU, GPU, NPU, TPU, or the like), and/or providing electrical connections for connecting the memory dies.

In some embodiments, rather than stacking memory dies (e.g., twelve or sixteen memory dies) vertically for access by the logic chip, the memory dies can be stacked, diced, vertically flipped or rotated by around ninety degrees, and/or bonded (e.g., perpendicularly bonded or bonded through a minor surface of the memory dies that is smaller than a major surface of the memory dies) to the logic chip to form a bonded structure (or simply referred to as a structure). As such, the bonded structure can include a plurality of memory dies, where each of the plurality of memory dies is bonded (e.g., through a minor surface) directly to the logic chip without through another memory die, and laterally spaced from each other rather than vertically stacked above or below each other. Further, each of the plurality of memory dies can communicate with the logic chip without the use of TSVs.

Advantageously, memory bandwidth and/or capacity may no longer be constrained by a height of a memory stack. Rather, memory bandwidth and/or capacity may increase by disposing memory dies laterally from each other on a surface of the logic chip so long as an area of the logic chip permits. Additionally, TSVs that traverse vertically across various memory dies in a memory stack to connect the memory dies to the logic chip can be eliminated or removed from the bonded structure. More specifically, the memory dies that are stacked and to be diced do not need to accommodate TSVs and areas reserved for deployment of TSVs, and each of the memory dies can be devoid of TSVs because each diced memory die can be bonded directly to the logic chip without through another diced memory die. For example, memory banks in a diced memory die can be connected to the logic chip through a redistribution layer (RDL) without through TSVs. By eliminating TSVs and area for routing or connecting TSVs within a memory die, more area and/or space within the memory die can be freed up for other purposes (e.g., deploying additional memory banks or cells). The degraded electrical performance, derivative thermal issues, and increased manufacturing complexity and cost associated with dense and/or long TSVs mentioned above can also be avoided or mitigated in the bonded structure.

Further, by connecting memory banks in a diced memory die directly to (e.g., through the RDL) the logic chip without through another memory die, memory access latency may be reduced. For example, rather than traversing laterally through conductive traces in a top memory die and vertically through TSVs from the top memory die to a logic chip below a memory stack, memory data in the bonded structure disclosed herein can simply traverse vertically through RDL to the logic chip. This can increase data transfer speed between memory dies and the logic chip. Further, yield associated with the bonded structure may improve by disposing redundant memory dies along a surface of the logic chip.

### Example Memory Architecture

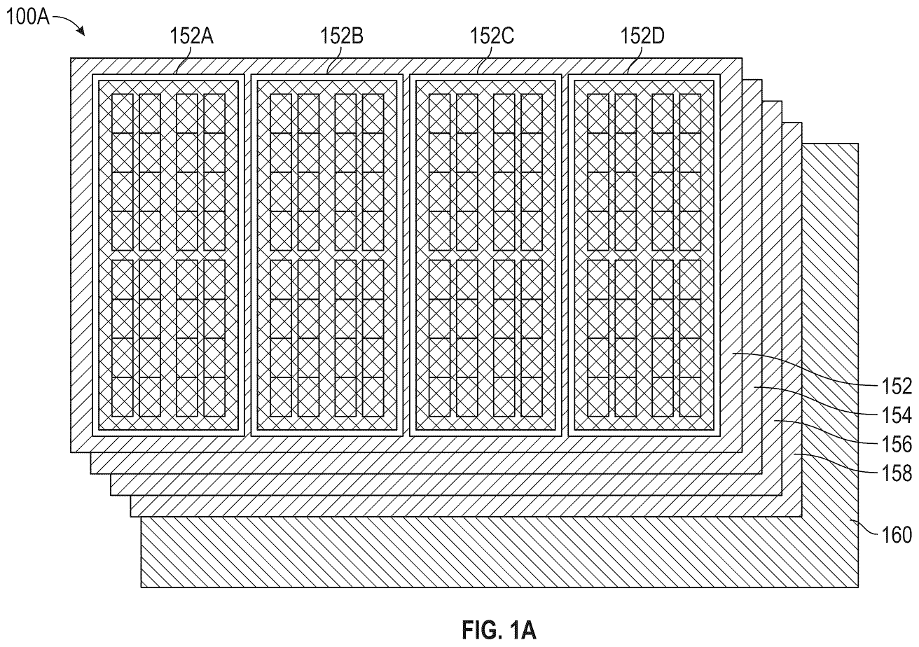

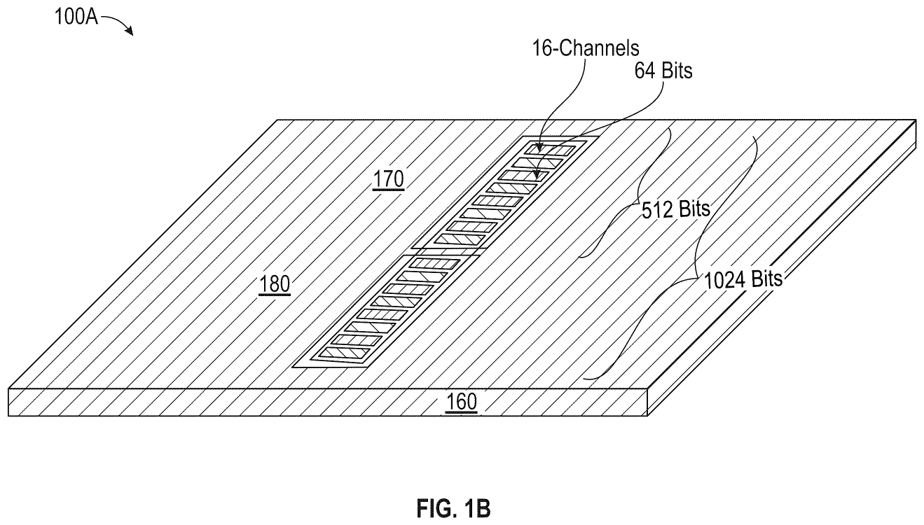

FIG. 1A illustrates an example memory architecture 100A including memory dies and a logic chip. The memory architecture 100A includes the logic chip 160, the memory die 152, the memory die 154, the memory die 156, and the memory die 158. Although FIG. 1A depicts 4 memory dies, memory stack can also have other number of dies; for example, 8 memory dies, 12 dies, 16 dies, and so on. For example, HBM3 architecture can have a maximum of 16 independent interfaces or memory channels. Other architectures can have dies with any other number of memory channels. Also, it should be understood that disclosed embodiments are discussed in the context using memory dies (e.g., the memory die 152, the memory die 154, the memory die 156, and the memory die 158) as examples. It should be appreciated that each of the memory dies 152, 154, 156, 158 can instead comprise any suitable type of a semiconductor element (e.g., a wafer, a die, an integrated circuit die, an integrated circuit wafer, and/or the like that can include semiconductor circuitry including memory circuitry, or circuitry that is not memory circuitry) in other embodiments of the present disclosure. As such, the present disclosure is not limited to dicing or singulating memory die(s). In the example depicted in FIG. 1A, each of the memory die 152, the memory die 154, the memory die 156, and the memory die 158 can include or support four memory channels or other number of memory channels. For example, as shown in FIG. 1A, the memory die 152 includes memory channel 152A, memory channel 152B, memory channel 152C, and memory channel 152D, where each of the memory channels 152A-152D may operate independently of each other to allow for parallel data processing. As such, the memory channels 152A-152D can be used simultaneously to read from or write to different parts (e.g., memory banks) in the memory architecture 100A, thereby improving the overall performance and efficiency. As indicated in FIG. 1A, the memory die 152, the memory die 154, the memory die 156, and the memory die 158 can communicate with the logic chip 160.

The logic chip 160 can be and/or include a memory controller, a base die, or a core die to serve as an interface between the memory stack (e.g., the memory dies 152, 154, 156, and 158) and other processor dies (not shown in FIG. 1A). The other processor dies can include central processing units (CPUs), graphical processing units (GPUs), field programmable gate arrays (FPGAs), Neural Processing Units (NPUs), Tensor Processing Units (TPUs), application specific integrated circuits (ASICs), or the like. The logic chip 160 can be configured to access and/or facilitate the other processor dies to access the memory die 152, the memory die 154, the memory die 156, and the memory die 158. For example, the logic chip 160 can manage read and write operations, facilitate communication between the memory dies 152, 154, 156, and 158 and the other processor dies or other semiconductor dies (not shown in FIG. 1A), or provide electrical connections for the memory dies 152, 154, 156, and 158.

Each of the memory die 152, the memory die 154, the memory die 156, and the memory die 158 can be a dynamic random-access memory (DRAM) die or a high bandwidth memory (HBM) die. In some embodiments, the memory architecture 100A (e.g., a HBM architecture or a HBM die stack) that includes the memory die 152, the memory die 154, the memory die 156, and the memory die 158 can have up to sixteen independent interfaces or sixteen memory channels. Each of the memory die 152, the memory die 154, the memory die 156, and the memory die 158 in the memory architecture 100A may additionally and/or optionally contributes additional capacity and channels, enhancing the overall memory bandwidth and capacity of the memory architecture 100A. In some embodiments, each channel (e.g., the memory channel 152A, the memory channel 152B, the memory channel 152C, and the memory channel 152D) can include a 64-bit data bus, with memory channel densities ranging from 2 Gigabits (Gb) to 32 Gbs. The memory architecture 100A can support configurations with 16, 32, 48, 64, or other numbers of (memory) banks per channel, depending on device density and selected channel configuration associated with the memory architecture 100A.

In some embodiments, each of the memory die 152, the memory die 154, the memory die 156, and the memory die 158 can flexibly support 1, 2, 4, 8, or other numbers of (memory) channels. For example, such flexibility can enable or support 16-channel configurations with stacks of 4 to 16 memory dies, while keeping all data for a given memory channel contained within a single die. In some embodiments, flip chip bumps or microbumps (e.g., ubumps) can be utilized to create electrical connections between various memory channels of the memory dies 152, 154, 156, and 158.

In some embodiments, the memory architecture 100A can include a pseudo channel (PC) that divides a channel into two sub-channels, each with 32-bit input/output (I/O). This division can provide a 256-bit prefetch per memory read and write access for each pseudo channel, enhancing data transfer efficiency.

FIG. 1B illustrates an example layout of memory channels in the memory architecture 100A of FIG. 1A. As shown in FIG. 1B, the memory architecture 100A can include 16 memory channels. The memory architecture 100A can be built on the logic chip 160. The logic chip 160 can be divided into a section 170 and a section 180.

In some embodiments, each of the section 170 and section 180 can include multiple memory channels (e.g., the memory channels 152A, 152B, 152C, and 152D). For example, the section 170 can include 8 memory channels, and the section 180 can include 8 memory channels. In some examples, each memory channel can be 64 bits wide, and the memory channels can be arranged in a way such that each section has 512 bits. The total bit width of the memory channels in the memory architecture 100A can be 1024 bits, where the 1024 bits can be distributed evenly across the 16 memory channels. In other examples, any other number of bits per channel, any other number of memory channels, any other number of bits per section, or the like can be used.

### Example Stacked Structures

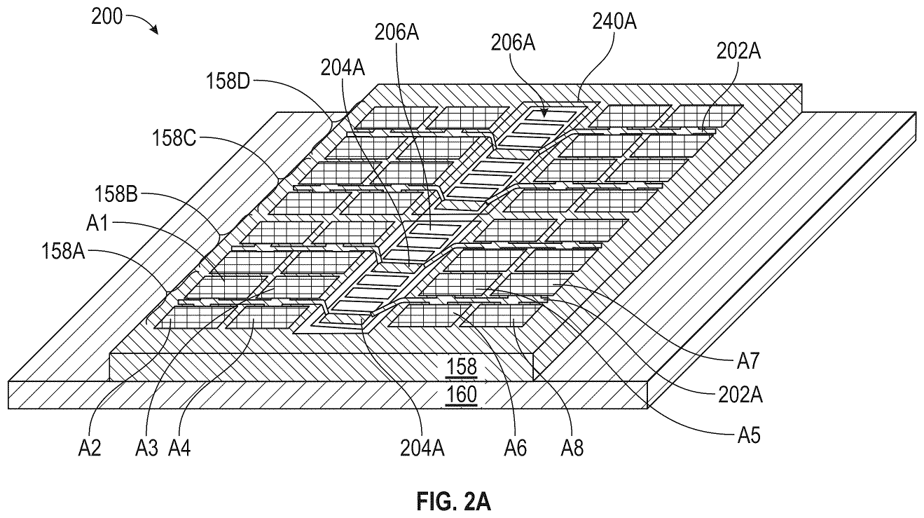

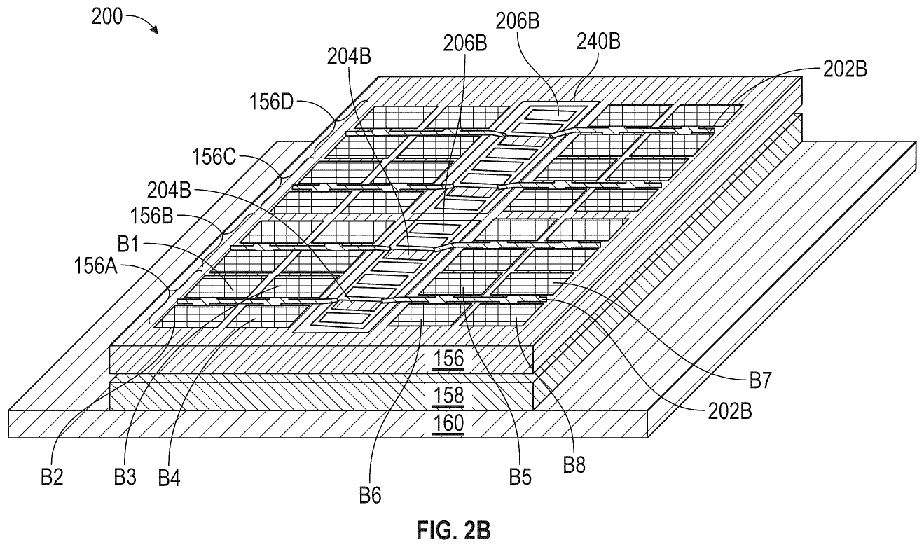

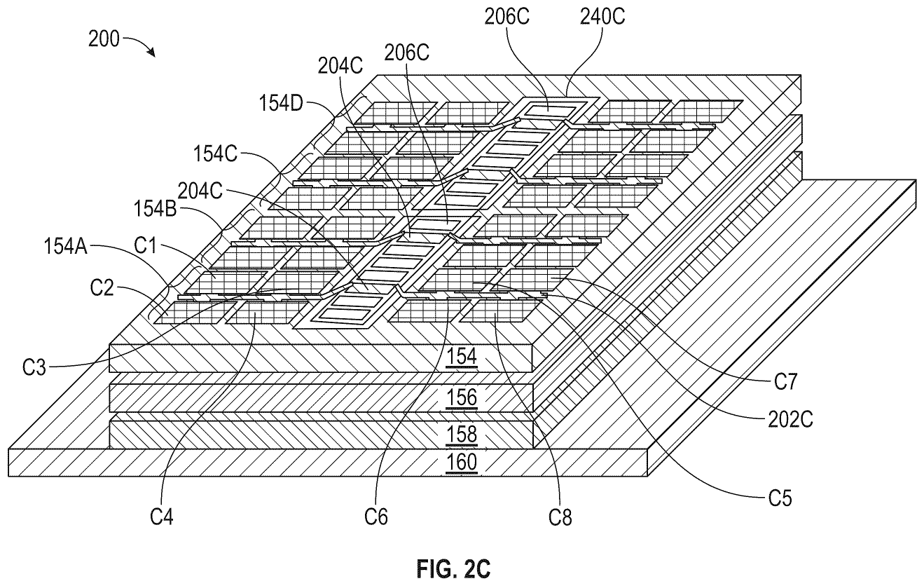

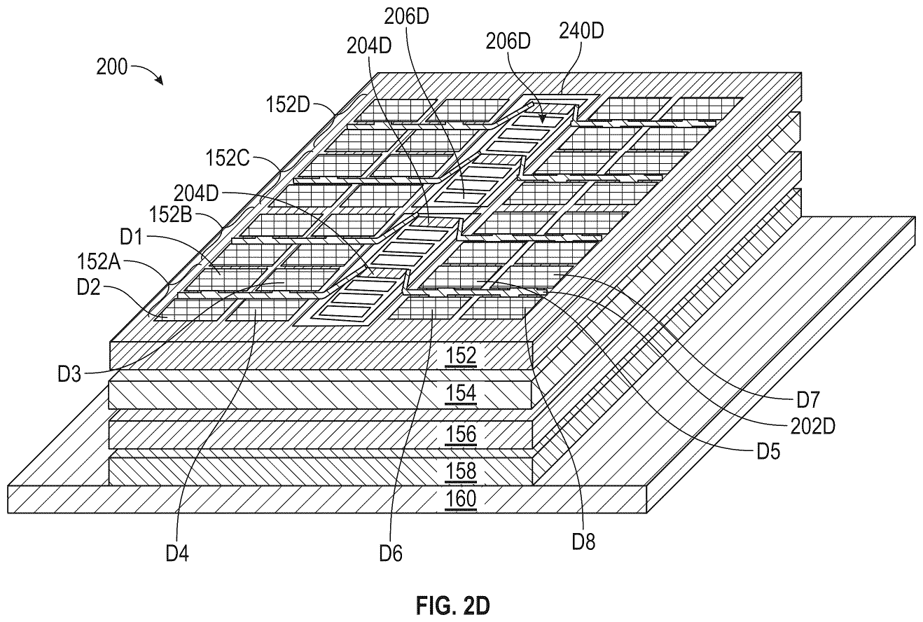

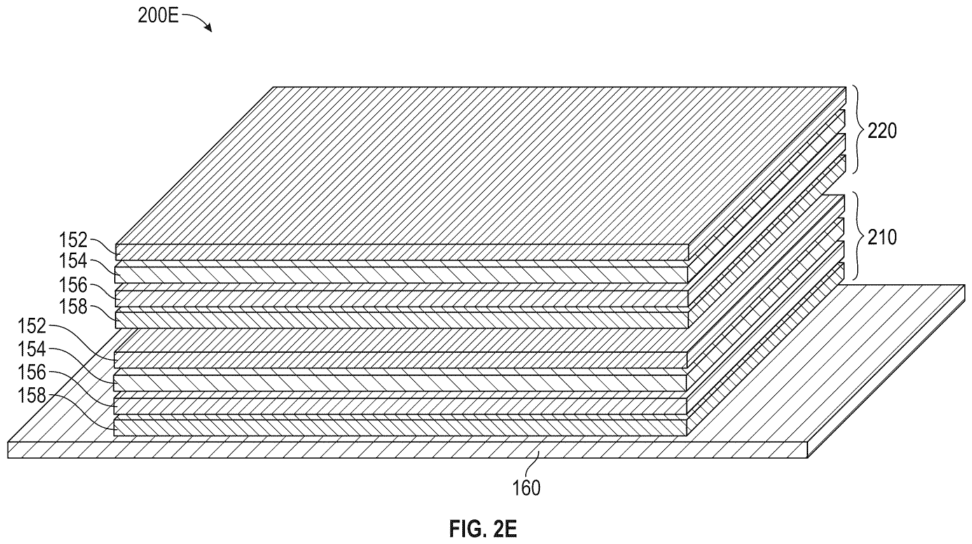

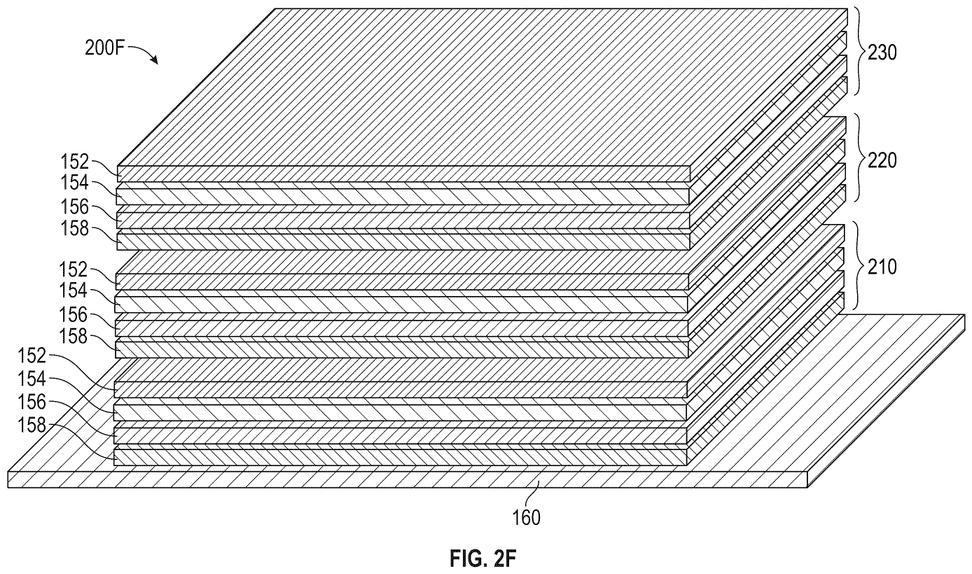

FIG. 2A illustrates a perspective view of a portion of an example bonded structure 200 for implementing the memory architecture 100A of FIG. 1A. As shown in FIG. 2A, the bonded structure 200 includes at least the logic chip 160 and the memory die 158. As noted above, the logic chip 160 can be and/or include a memory controller, a base die, or a core die to serve as an interface between the memory stack (e.g., the memory dies 152, 154, 156, and 158) and other processor dies (not shown in FIG. 2A). The other processor dies can include central processing units (CPUs), graphical processing units (GPUs), field programmable gate arrays (FPGAs), Neural Processing Units (NPUs), Tensor Processing Units (TPUs), application specific integrated circuits (ASICs), or the like. The logic chip 160 can be configured to access the memory die 158 and manage read and write operations, facilitate communication between the memory die 158 and the other processor or semiconductor dies (not shown in FIG. 2A), or provide electrical connections for the memory die 158.

The memory die 158 includes at least a memory channel 158A, a memory channel 158B, a memory channel 158C, a memory channel 158D, electrical connections 202A, through-substrate-vias (TSVs) 204A, and bypass TSVs 206A. The TSVs 204A and the bypass TSVs 206A are illustrated to be in an interconnect region 240A that is deployed to accommodate the TSVs 204A and the bypass TSVs 206A. As noted above, each of the memory channels 158A, 158B, 158C, and 158D in the memory die 158 can include a 64-bit data bus, with channel densities ranging from 2 Gbs to 32 Gbs. The memory die 158 can communicate with the logic chip 160. In some embodiments, the electrical connections 202A can be formed in wiring layers (e.g., redistribution layer (RDL) or other wiring layers with conductive traces and/or vias embedded in an insulating material) that are formed over an active surface of the memory die 158. As shown in FIG. 2A, each of the memory channel 158A, the memory channel 158B, the memory channel 158C, and the memory channel 158D can include a plurality of (e.g., eight) memory banks that are electrically connected with each other through the electrical connection 202A. For example, the electrical connection 202A can include one or more conductive (e.g., metallic material such as copper) traces or wires that electrically connect the eight memory banks (e.g., the memory bank A1, the memory bank A2, the memory bank A3, the memory bank A4, the memory bank A5, the memory bank A6, the memory bank A7, and the memory bank A8) of the memory channel 158A. Besides electrically connecting the eight memory banks of the memory channel 158A, the electrical connection 202A is further electrically connected to the TSV 204A.

The TSVs 204A can provide vertical electrical connections through the memory die 158 (e.g., through a silicon substrate of the memory die 158). The TSVs 204A can enable the logic chip 160 to access the memory die 158, thereby facilitating efficient data transfer and communication. For example, through the electrical connection 202A and the TSV 204A, the logic chip 160 can access each of the eight memory banks in the memory channel 158A.

The bypass TSVs 206A can provide vertical electrical connections to enable communication between other memory dies (e.g., the memory die 152, the memory die 154, and the memory die 156 shown in FIGS. 2B, 2C, and 2D) and the logic chip 160, instead of providing vertical electrical connections to enable communication between the memory die 158 and the logic chip 160. Although the bypass TSVs 206A are not needed to enable communication between the memory die 158 and the logic chip 160, the bypass TSVs 206A are still utilized in the memory die 158 to facilitate communications between the logic chip 160 and other memory dies in the stack.

FIG. 2B illustrates a perspective view of a portion of the bonded structure 200 for implementing the memory architecture 100A of FIG. 1A. Unless otherwise noted, the components of FIG. 2B can be structurally and/or functionally the same as or generally similar to like-numbered components of FIG. 2A. In contrast to FIG. 2A, FIG. 2B shows that the bonded structure 200 further includes the memory die 156.

The memory die 156 includes at least a memory channel 156A, a memory channel 156B, a memory channel 156C, a memory channel 156D, electrical connections 202B, through-substrate-vias (TSVs) 204B, and bypass TSVs 206B. The TSVs 204B and the bypass TSVs 206B are illustrated to be in an interconnect region 240B. As shown in FIG. 2A, each of the memory channel 156A, the memory channel 156B, the memory channel 156C, and the memory channel 156D includes eight memory banks that are electrically connected with each other through the electrical connection 202B. For example, the electrical connection 202B can include one or more conductive (e.g., metallic material such as copper) traces or wires that electrically connect the eight memory banks (e.g., the memory bank B1, the memory bank B2, the memory bank B3, the memory bank B4, the memory bank B5, the memory bank B6, the memory bank B7, and the memory bank B8) of the memory channel 156A. Besides electrically connecting the eight memory banks of the memory channel 156A, the electrical connection 202B is further electrically connected to the TSV 204B.

The TSVs 204B can provide vertical electrical connections through the memory die 156. The TSVs 204B can bypass through the memory die 158 to electrically connect the memory die 156 and the logic chip 160. The TSVs 204B can enable the logic chip 160 to access memory banks in the memory die 156, thereby facilitating efficient data transfer and communication. For example, through the electrical connection 202B and the TSV 204B, the logic chip 160 can access each of the eight memory banks in the memory channel 156A.

The bypass TSVs 206B can provide vertical electrical connections to enable communication between other memory dies (e.g., the memory die 152 and the memory die 154) and the logic chip 160, instead of providing vertical electrical connections to enable communication between the memory die 156 and the logic chip 160. Although the bypass TSVs 206B are not needed to enable communication between the memory die 156 and the logic chip 160, the bypass TSVs 206B still are deployed in the memory die 156 to facilitate communications between the logic chip 160 and other memory dies.

FIG. 2C illustrates a perspective view of a portion of the bonded structure 200 for implementing the memory architecture 100A of FIG. 1A. Unless otherwise noted, the components of FIG. 2C can be structurally and/or functionally the same as or generally similar to like-numbered components of FIGS. 2A-2B. In contrast to FIG. 2B, FIG. 2C shows that the bonded structure 200 further includes the memory die 154.

The memory die 154 includes at least a memory channel 154A, a memory channel 154B, a memory channel 154C, a memory channel 154D, electrical connections 202C, through-substrate-vias (TSVs) 204C, and bypass TSVs 206C. The TSVs 204C and the bypass TSVs 206C are illustrated to be in an interconnect region 240C. As shown in FIG. 2C, each of the memory channel 154A, the memory channel 154B, the memory channel 154C, and the memory channel 154D includes eight memory banks that are electrically connected with each other through the electrical connection 202C. For example, the electrical connection 202C can electrically connect the eight memory banks (the memory bank C1, the memory bank C2, the memory bank C3, the memory bank C4, the memory bank C5, the memory bank C6, the memory bank C7, and the memory bank C8) of the memory channel 154A. Besides electrically connecting the eight memory banks of the memory channel 154A, the electrical connection 202C is further electrically connected to the TSV 204C.

The TSVs 204C can provide vertical electrical connections through the memory die 154. The TSVs 204C can bypass through the memory die 156 and the memory die 158 to electrically connect the memory die 154 and the logic chip 160. The TSVs 204C can enable the logic chip 160 to access the memory die 154, thereby facilitating efficient data transfer and communication. For example, through the electrical connection 202C and the TSV 204C, the logic chip 160 can access each of the eight memory banks in the memory channel 154A.

The bypass TSVs 206C can provide vertical electrical connections to enable communication between other memory dies (e.g., the memory die 152) and the logic chip 160, instead of providing vertical electrical connections to enable communication between the memory die 154 and the logic chip 160. Although the bypass TSVs 206C are not needed to enable communication between the memory die 154 and the logic chip 160, the bypass TSVs 206C still are deployed in the memory die 154 to facilitate communications between the logic chip 160 and other memory dies FIG. 2D illustrates a perspective view of a portion of the bonded structure 200 for implementing the memory architecture 100A of FIG. 1A. Unless otherwise noted, the components of FIG. 2D can be structurally and/or functionally the same as or generally similar to like-numbered components of FIGS. 2A-2C. In contrast to FIG. 2C, FIG. 2D shows that the bonded structure 200 further includes the memory die 152. In some embodiments, the memory die 152 can be hybrid bonded to the memory die 154, the memory die 154 can be hybrid bonded to the memory die 156, the memory die 156 can be hybrid bonded to the memory die 158, and/or the memory die 158 can be hybrid bonded to the logic chip 160.

The memory die 152 includes at least a memory channel 152A, a memory channel 152B, a memory channel 152C, a memory channel 152D, electrical connections 202D, through-substrate-vias (TSVs) 204D, and bypass TSVs 206D. The TSVs 204D and the bypass TSVs 206D are illustrated to be in an interconnect region 240D. As shown in FIG. 2D, each of the memory channel 152A, the memory channel 152B, the memory channel 152C, and the memory channel 152D includes eight memory banks that are electrically connected with each other through the electrical connection 202D. For example, the electrical connection 202D can electrically connect the eight memory banks (the memory bank D1, the memory bank D2, the memory bank D3, the memory bank D4, the memory bank D5, the memory bank D6, the memory bank D7, and the memory bank D8) of the memory channel 152A. Besides electrically connecting the eight memory banks of the memory channel 152A, the electrical connection 202D is further electrically connected to the TSV 204D.

The TSVs 204D can provide vertical electrical connections through the memory die 152. The TSVs 204D can bypass through the memory dies 154, 156, and 158 to electrically connect the memory die 152 and the logic chip 160. The TSVs 204D can enable the logic chip 160 to access the memory die 152, thereby facilitating efficient data transfer and communication. For example, through the electrical connection 202D and the TSV 204D, the logic chip 160 can access each of the eight memory banks in the memory channel 152A.

FIG. 2E illustrates a diagram of a stacked memory (e.g., a bonded structure, a structure formed using direct bonding techniques, a structure formed using adhesives, or the like) structure 200E including two groups of memory dies stacked above the logic chip 160. The stacked memory structure 200E can be obtained based on the bonded structure 200 shown in FIG. 2D by further stacking another group of memory dies that includes the memory dies 158, 156, 154, and 152. For example, the stacked memory structure 200E can be obtained by vertically stacking a memory group 220 over a memory group 210 and the logic chip 160, where each of the memory groups 210 and 220 includes the memory dies 158, 156, 154, and 152 vertically stacked with each other. In some embodiments, memory dies in the same memory group can share certain data pathways and/or control signals. For example, the memory dies 158, 156, 154, and 152 in the memory group 210 can be accessed by the logic chip 160 through some shared control signals (e.g., memory read, memory read, chip select, and/or memory enable signals). In contrast, memory dies in different memory groups can be accessed by different sets of control signals.

FIG. 2F illustrates a diagram of a stacked memory structure 200F (e.g., a bonded structure, a structure formed using direct bonding techniques, a structure formed using adhesives, or the like) including three groups of memory dies stacked above the logic chip 160. The stacked memory structure 200F can be obtained based on the stacked memory structure 200E shown in FIG. 2E by further stacking another group of memory dies that includes the memory dies 158, 156, 154, and 152. For example, the stacked memory structure 200F can be obtained by vertically stacking a memory group 210, a memory group 220, and a memory group 230, where each of the memory groups 210, 220, and 230 includes the memory dies 158, 156, 154, and 152 vertically stacked with each other. In some embodiments, at least some of the memory dies 158, 156, 154, and 152 can be directly bonded to each other. For example, at least some of the memory dies 158, 156, 154, and 152 (e.g., a memory die 158 and a memory die 156) can be uniformly bonded (e.g., bonding using only dielectrics without metals) to each other. As another example, at least some of the memory dies 158, 156, 154, and 152 (e.g., a memory die 158 and a memory die 152) can be hybrid bonded (e.g., bonding using both dielectrics and metals) to each other.

In the bonded structures 200, 200E, and/or 200F, the memory dies 158, 156, 154, and 152 can communicate with the logic chip 160 through TSVs 204A, 204B, 204C, or 204D and/or bypass TSVs 206A, 206B, 206C, or 206D. The TSVs 204A, 204B, 204C, or 204D, and the bypass TSVs 206A, 206B, 206C, or 206D may occupy considerable space (e.g., considerable lateral chip real estate) within the bonded structure 200 (e.g., a HBM memory stack), which may incur significant cost for manufacturing the memory stack and/or packaging the memory stack into semiconductor packages. Further, additional or increased resistance in electrical connections between the logic chip 160 and the memory dies 158, 156, 154, and 152 may be introduced because of presence of the TSVs 204A, 204B, 204C, and 204D, or the bypass TSVs 206A, 206B, 206C, and 206D. The increased resistance may degrade electrical characteristic or performance (e.g., more electrical energy wasted due to increased resistance) associated with the bonded structure 200. Increased amount or usage of TSVs 204A, 204B, 204C, and 204D, or the bypass TSVs 206A, 206B, 206C, and 206D and other interconnect structures (e.g., the interconnect regions 240A, 240B, 240C, or 240D) can also lead to thermal issues associated with the bonded structure 200. For example, long TSVs may impede efficient heat dissipation, leading to hotspots and potential thermal stress across a memory stack. Still, the complexity and cost of manufacturing or assembling the bonded structure 200 may increase because of increased use of interconnect structures (e.g., the interconnect regions 240A, 240B, 240C, or 240D). This may negatively impact yield and reliability of the bonded structure 200, affecting overall performance of semiconductor devices

As noted above, some implementations disclosed herein can reduce or eliminate the use of the TSVs 204A, 204B, 204C, and 204D, or the bypass TSVs 206A, 206B, 206C, and 206D but nevertheless can still electrically connect the memory dies 158, 156, 154, and 152 to the logic chip 160 by dicing (e.g., through one or more singulation process), orienting, and/or bonding the memory dies 158, 156, 154, and 152 to the logic chip 160. In some embodiments, rather than stacking memory dies 158, 156, 154, and 152 (e.g., twelve or sixteen memory dies) vertically for access by the logic chip 160, the memory dies 158, 156, 154, and 152 can be diced, vertically flipped or rotated by around ninety degrees, and bonded (e.g., perpendicularly bonded or bonded through a minor surface) to the logic chip 160 to form a bonded structure (e.g., a bonded structure 400A or a bonded structure 400B that is formed based on a stacked memory structure 300, or a bonded structure 600A or a bonded structure 600B that is formed based on a stacked memory structure 500). As such, the bonded structure can include a plurality of memory dies, where each of the plurality of memory dies is bonded (e.g., through a minor surface) directly to the logic chip 160, and laterally spaced from each other rather than vertically stacked above or below each other.

### Example Stacked Structures

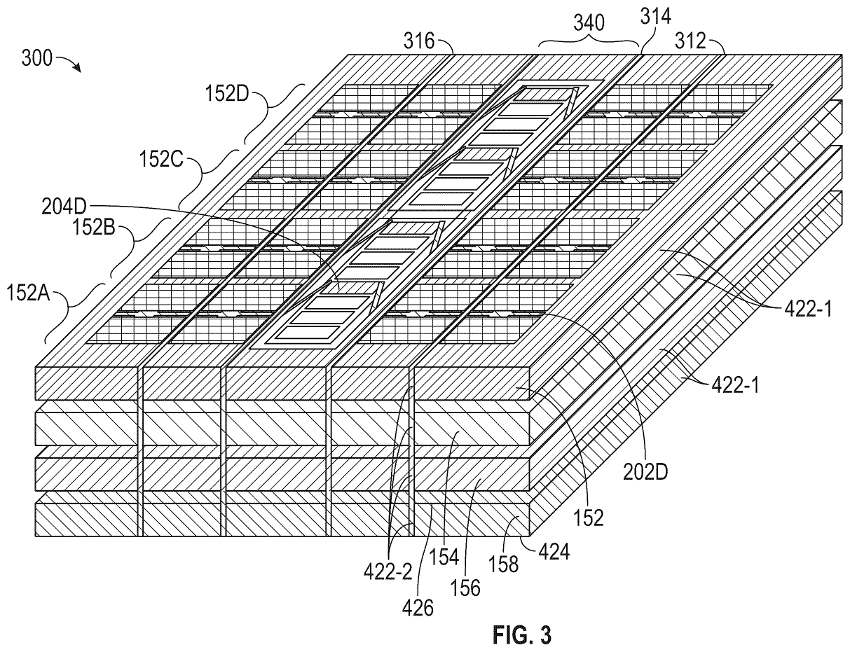

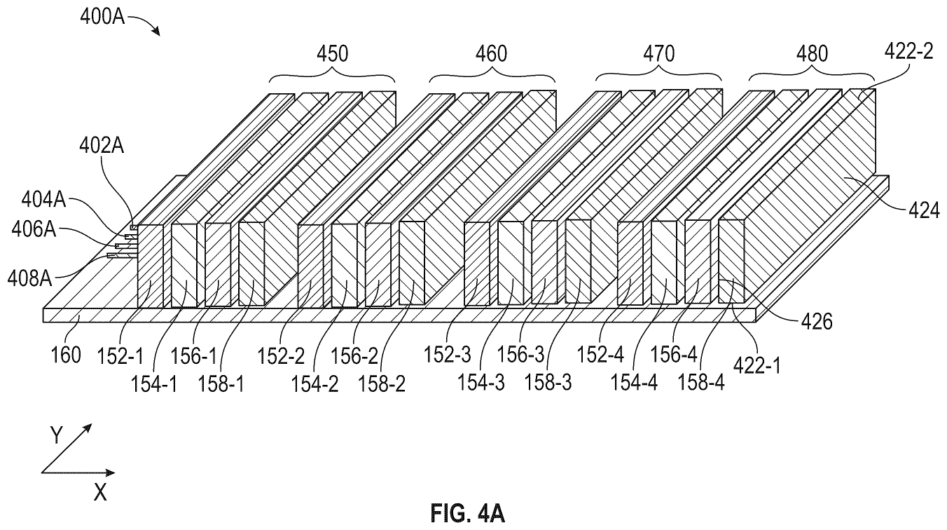

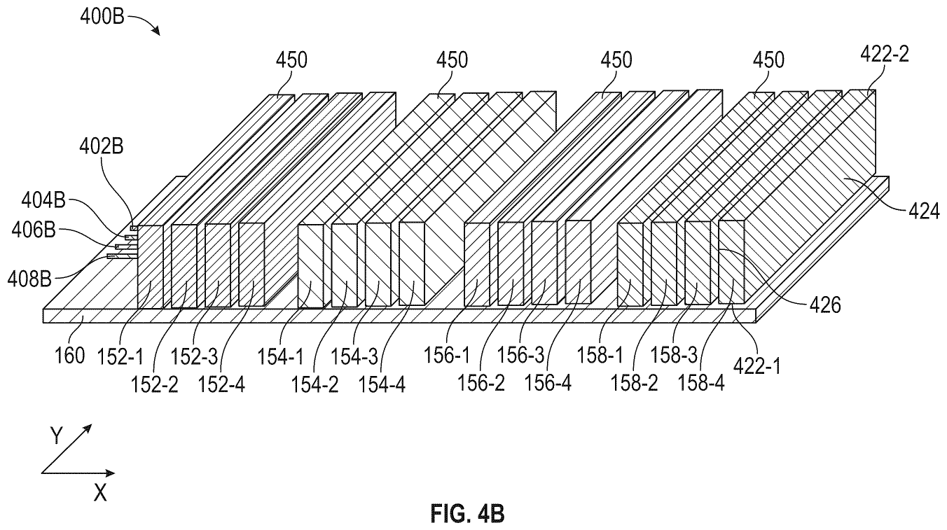

FIG. 3 illustrates a perspective view of an example stacked memory structure 300 (e.g., DRAM or high bandwidth memory dies) to be singulated along a first direction (e.g., a direction normal to the memory channels 152A, 152B, 152C, or 152D, a direction normal to the active surfaces and the bonding surfaces of the memory dies 152, 154, 156, and 158) for implementing the memory architecture 100A of FIG. 1A according to some embodiments. Unless otherwise noted, the components of FIG. 3 can be structurally and/or functionally the same as or generally similar to like-numbered components of FIGS. 2A-2D. As shown in FIG. 3, the stacked memory structure 300 includes the memory die 158, the memory die 156, the memory die 154, and the memory die 152 that are vertically stacked. Although not illustrated in FIG. 3, the stacked memory structure 300 can include fewer or more memory dies. For example, the bonded structure can include the memory die 158 without including the memory dies 156, 154, and 152. As shown in FIG. 3, the stacked memory structure 300 also shows a top major surface 424, a bottom major surface 426, and a minor surface 422-1 (e.g., a bottom minor surface), and a minor surface 422-2 (e.g., a top minor surface) of the memory die 158 that can be exposed through one or more singulation processes and will be described with reference to FIGS. 4A and 4B.

In FIG. 3, an interconnect region 340 (e.g., a region similar to the interconnect regions 240A, 240B, 240C, or 240D that includes TSVs and/or bypass TSVs) that is not needed or present for the stacked memory structure 300 is nevertheless shown solely for illustrative purpose. In contrast to the interconnect regions 240A, 240B, 240C, and 240D of the bonded structure 200, the interconnect region 340 and the TSVs 204D are significantly reduced or not needed for the stacked memory structure 300 and can be physically removed or omitted from the stacked memory structure 300 according to embodiments of the present disclosure. In the absence of the interconnect region 340, the electrical connection 202D can still connect, for example, the eight memory banks of the memory channel 152A without the use of TSVs (e.g., the TSV 204D).

In some embodiments, the stacked memory structure 300 can be singulated (e.g., diced or through any suitable manner such as sawing, etching, or the like) along the singulation street 316, the singulation street 314, and/or the singulation street 312. For example, after singulating the stacked memory structure 300 along the singulation streets 316, 314, and 312, the memory die 152 can be diced into four memory dies (e.g., the memory dies 152-1, 152-2, 152-3, and 152-4 shown in FIG. 4A). The four memory dies can be oriented (e.g., vertically flipped or rotated by around ninety degrees) and bonded to the logic chip 160 (e.g., a base chip, a core chip, a memory controller chip, etc.) to form the structure 400A of FIG. 4A or the structure 400B of FIG. 4B. In some embodiments, the structure 400A of FIG. 4A shows different memory channels in the same memory group or rank are grouped together or disposed adjacent to each other. The structure 400B of FIG. 4B shows the same memory channels from different memory groups or ranks are grouped together or disposed adjacent to each other.

FIG. 4A illustrates a perspective view of an example bonded structure 400A obtained from singulating, orienting, and/or bonding high bandwidth memory dies 158, 156, 154, and 152 of the stacked memory structure 300 of FIG. 3 according to some embodiments. As shown in FIG. 4A, the bonded structure 400A includes the logic chip 160, a memory group 450, a memory group 460, a memory group 470, and a memory group 480. The memory group 450 includes a memory die 152-1, a memory die 154-1, a memory die 156-1, and a memory die 158-1. The memory group 460 includes a memory die 152-2, a memory die 154-2, a memory die 156-2, and a memory die 158-2. The memory group 470 includes a memory die 152-3, a memory die 154-3, a memory die 156-3, and a memory die 158-3. The memory group 480 includes a memory die 152-4, a memory die 154-4, a memory die 156-4, and a memory die 158-4. The memory dies 152-1, 152-2, 152-3, and 152-4 can be diced from the memory die 152 shown in FIG. 3. The memory dies 154-1, 154-2, 154-3, and 154-4 can be diced from the memory die 154 shown in FIG. 3. The memory dies 156-1, 156-2, 156-3, and 156-4 can be diced from the memory die 156 shown in FIG. 3. The memory dies 158-1, 158-2, 158-3, and 158-4 can be diced from the memory die 158 shown in FIG. 3.

As shown in FIG. 4A, the diced memory dies are bonded to the logic chip 160. Each of the diced memory dies is electrically connected to the logic chip 160 through conductor 402A, conductor 404A, conductor 406A, or conductor 408A. For example, each of the memory dies 152-1, 152-2, 152-3, and 152-4 is electrically connected to the logic chip 160 through the conductor 402A; each of the memory dies 154-1, 154-2, 154-3, and 154-4 is electrically connected to the logic chip 160 through the conductor 404A, each of the memory dies 156-1, 156-2, 156-3, and 156-4 is electrically connected to the logic chip 160 through the conductor 406A; and each of the memory dies 158-1, 158-2, 158-3, and 158-4 is electrically connected to the logic chip 160 through the conductor 408A. In some embodiments, the conductor 402A, the conductor 404A, the conductor 406A, and/or the conductor 408A can be formed in back-end-of-line (BEOL) layers that are formed on the logic chip 160. Each of the conductor 402A, the conductor 404A, the conductor 406A, and the conductor 408A can extend or route under and through the memory group 450 (e.g., a first rank), the memory group 460 (e.g., a second rank), and the memory group 470 (e.g., a third rank), and at least partially through the memory group 480 (e.g., a fourth rank) to electrically connect respective memory dies that are to be addressed. As such, the conductor 402A, the conductor 404A, the conductor 406A, and/or the conductor 408A may connect or provide common memory channels associated with the memory dies in the memory groups 450, 460, 470, and 480. Although conductor 402A, conductor 404A, conductor 406A, or conductor 408A are shown to be in the middle/center of the top surface of the logic chip 160 (e.g., indicating contacts between memory dies 152-1, 154-1, 156-1, and 158-1 and the logic chip 160 may be limited towards the central portion of the bonded structure 400A along the Y axis, it will be understood that interconnects can be distributed over the entire length (e.g., along the X axis) and/or width (e.g., along the Y axis) of the logic chip 160.

In some embodiments, each of the memory dies diced from the memory dies 152, 154, 156, and/or 158 can be bonded to the logic chip 160 through a minor surface (e.g., a surface with smaller area, a side surface of the memory dies) rather than major surfaces (e.g., surfaces with larger area than the minor surface, an active surface of the memory dies). For example, the memory die 158-4 can include a bottom minor surface 422-1, a top minor surface 422-2, a top major surface 424, and a bottom major surface 426 (the bottom minor surface 422-1, the top minor surface 422-2, the top major surface 424, and the bottom major surface 426 also identified in FIG. 3). The bottom minor surface 422-1 and the top minor surface 422-2 can be non-parallel to the top major surface 424 and the bottom major surface 426. The top major surface 424 can be parallel to the bottom major surface 426. An area of the bottom minor surface 422-1 or the top minor surface 422-2 is less than an area of the top major surface 424 or an area of the bottom major surface 426. For example, a length (e.g., a distance of the bottom minor surface 422-1 along the Y axis) of the bottom minor surface 422-1 can be the same as a length (e.g., a distance of the top major surface 424 along the Y axis) of the top major surface 424, but the width (e.g., a distance of the bottom minor surface 422-1 along the X axis that can be between 40 micrometers to 700 micrometers) of the bottom minor surface 422-1 can be less than as a width (e.g., a distance of the top major surface 424 along the direction perpendicular to a plane formed by the X axis and the Y axis that can be between 1 mm to 8 mm) of the top major surface 424. The bottom minor surface 422-1 and/or the top minor surface 422-2 can be created by dicing the memory die 158 along the singulation streets 316, 314, or 312 as shown in FIG. 3. The top minor surface 422-2 may include artifacts (e.g., saw striations, markings, plasma etching artifacts, or the like) indicative of at least a singulation process applied on the memory die 158. Further, the top minor surfaces 422-2 of memory dies (e.g., the memory die 152-4, the memory die 154-4, the memory die 156-4, and the memory die 158-4) in a particular rank can be flush with each other due to a singulation process along the singulation street 312. Instead of bonding the memory die 158-4 to the logic chip 160 through the top major surface 424 or the bottom major surface 426, the memory die 158-4 can be vertically flipped or rotated by about ninety degrees after being diced from the memory die 158, and bonded (e.g., hybrid bonded) to or otherwise (e.g., using flip chip bumps, microbumps, solder bumps) attached to the logic chip 160 through the bottom minor surface 422-1. In some embodiments, the bottom minor surface 422-1 can be prepared for hybrid bonding (e.g., planarized, activated, or the like) such that the bottom minor surface 422-1 of a particular rank can form a hybrid bonding surface that hybrid bonds to the logic die 160. The logic chip 160 can then access the memory die 158-4 (e.g., the memory banks Al or A2 shown in FIG. 2A) at least through the bottom minor surface 422-1, the conductor 408A, and/or the electrical connection(s) 202A. As such, the bonded structure 400A can include a plurality of memory dies (e.g., the memory dies 152-1, 154-2, 156-3, and 158-3), where each of the plurality of memory dies is bonded (e.g., through a minor surface such as the bottom minor surface 422-1) directly to the logic chip 160 without through another memory die.

FIG. 4B illustrates a perspective view of an example bonded structure 400B obtained from singulating, orienting, and/or bonding high bandwidth memory dies 152, 154, 156, and 158 of the stacked memory structure 300 of FIG. 3 according to some embodiments. Unless otherwise noted, the components of FIG. 4B can be structurally and/or functionally the same as or generally similar to like-numbered components of FIG. 4A. In contrast to the bonded structure 400A where memory dies (e.g., the memory dies 152-1, 154-1, 156-1, and 158-1) in the same group (e.g., the memory group 450) or diced from different memory dies (e.g., the memory dies 152, 154, 156, and 158) are physically disposed to be adjacent with each other, memory dies diced from the same memory dies are physically disposed to be adjacent with each other in the bonded structure 400B. For example, the memory dies 152-1, 152-2, 152-3, and 152-4 that are diced from the memory die 152 are adjacent to each other in the bonded structure 400B without another memory die (e.g., the memory dies 154-1, 156-1, or 158-1) that is not diced from the memory die 152 in between.

As shown in FIG. 4B, each of the diced memory dies is electrically connected to the logic chip 160 through conductor 402B, conductor 404B, conductor 406B, or conductor 408B. For example, each of the memory dies 152-1, 152-2, 152-3, and 152-4 is electrically connected to the logic chip 160 through the conductor 402B; each of the memory dies 154-1, 154-2, 154-3, and 154-4 is electrically connected to the logic chip 160 through the conductor 404B; each of the memory dies 156-1, 156-2, 156-3, and 156-4 is electrically connected to the logic chip 160 through the conductor 406B; and each of the memory dies 158-1, 158-2, 158-3, and 158-4 is electrically connected to the logic chip 160 through the conductor 408B.

Similar to the bonded structure 400A, in the bonded structure 400B, the logic chip 160 can access each of the diced memory dies at least through the minor surfaces of the diced memory dies, the conductor 402B, 404B, 406B, or 408B, and/or the electrical connections 202A, 202B, 202C, or 202D. For example, the logic chip 160 can access the memory dies 158-1, 158-2, 158-3, and 158-4 through the bottom minor surface(s) 422-1, the conductor 408B, and the electrical connections 202A. As such, the bonded structure 400A or 400B can be functionally the same or similar to the bonded structure 200, where the logic chip 160 can access memory banks of the memory dies 158, 156, 154, and 152. In some embodiments, a diced memory die can be hybrid bonded to another diced memory die. For example, the memory dies 158-1 and 158-2 can be hybrid bonded to each other; the memory dies 158-2 and 158-3 can be hybrid bonded to each other; and the memory dies 158-3 and 158-4 can be hybrid bonded to each other. Alternatively, a diced memory die can be bonded to another diced memory die using adhesive. For example, the memory dies 158-1 and 158-2 can be bonded to each other using adhesive; the memory dies 158-2 and 158-3 can be bonded to each other using adhesive; and the memory dies 158-3 and 158-4 can be bonded to each other using adhesive.

In contrast to the implementations in the bonded structure 200 where memory dies are vertically stacked above or below each other and accessed by the logic chip 160 through TSVs, each of the memory dies in the bonded structures 400A or 400B can be laterally spaced from each other and deployed on a surface of the logic chip 160 (e.g., minor surfaces of memory dies are hybrid bonded to the logic chip 160, and the memory dies within each rank or group are hybrid bonded to one another along major surfaces) to be accessed by the logic chip 160 without the use of TSVs, which can achieve the following advantages. First, memory bandwidth and/or capacity associated with the bonded structures 400A and 400B may no longer be constrained by a height of a memory stack (e.g., the memory stack shown in FIG. 2D). Rather, memory bandwidth and/or capacity may increase by disposing memory dies laterally from each other on a surface of the logic chip 160 so long as an area of the logic chip 160 permits. Additionally, TSVs that traverse vertically across various memory dies in the memory stack of FIG. 2D to connect the memory dies 152, 154, 156, and 158 to the logic chip 160 can be eliminated from the bonded structures 400A and 400B. More specifically, each of the memory dies 152, 154, 156, and 158 that are stacked as shown in FIG. 3 and to be diced along the singulation streets 316, 314, and 312 do not need to accommodate TSVs (e.g., the interconnect region 340 are not needed and are removed) and enables the use of BEOL processes to form routing layers more easily and cost effectively compared with the formation of TSVs. Each diced memory die as shown in FIGS. 4A-4B can be devoid of TSVs and bonded directly to the logic chip 160 without through another memory die. By eliminating TSVs and associated areas (e.g., the interconnect regions 240A, 240B, 240C, and 240D) within memory dies 152, 154, 156, and 158, more area and/or space within the memory dies 152, 154, 156, and 158 can be freed up for other purposes (e.g., deploying additional memory banks or cells). The degraded electrical performance, derivative thermal issues, decreased yield, and increased manufacturing complexity and cost associated with dense and/or long TSVs can also be avoided or mitigated in the bonded structure 400A or 400B. In contrast to existing memory stacks that rely on known good dies (e.g., entire memory stack can be rendered unusable if one memory die fails), replacing a failed die can be more straightforward in the bonded structure 400A or 400B, where memory dies are disposed in parallel (rather than disposed vertically with each other). As such, the bonded structure 400A or 400B can allow or achieve improved process and stacking yield. Additionally, existing memory stacking methods tend to become overly complex when stacking more than 8 to 12 memory dies, the bonded structure 400A or 400B is much more accommodating with respect to number of memory dies integrated, and can allow for stacking as high as 64, 128, or even 256 memory dies.

U.S. Pat. Nos. 12,015,010 or 12,009,349 discloses a semiconductor device that includes a first semiconductor die, a second semiconductor die including a side surface bonded to the first semiconductor die, such that the second semiconductor die is perpendicular to the first semiconductor die, and a junction circuit for connecting the first semiconductor die to the second semiconductor die. By contrast, the present disclosure includes embodiments that dice (e.g., through one or more singulation processes applied on a wafer) stacked memory dies and bond memory dies to a logic chip. As such, each of the memory dies can be bonded (e.g., through a minor surface) directly to the logic chip without through another memory die, and laterally spaced from each other rather than vertically stacked above or below each other. Each of the memory dies can communicate with the logic chip without the use of TSVs. Additionally, memory dies associated with different memory channels in the same memory group and/or memory dies associated with same memory channels from different memory groups can be disposed adjacent to each other, and the memory dies can be connected through conductors (e.g., the conductor 402A, the conductor 404A, the conductor 406A, the conductor 408A, the conductor 402B, the conductor 404B, the conductor 406B, or the conductor 408B) that extend or route under the memory dies such that each memory die can be addressed by the logic chip. Advantageously, memory bandwidth and/or capacity may no longer be constrained by a height of a memory stack. Rather, memory bandwidth and/or capacity may increase by disposing memory dies laterally from each other on a surface of the logic chip so long as an area of the logic chip permits. Additionally, TSVs that traverse vertically across various memory dies in a memory stack to connect the memory dies to the logic chip can be eliminated or removed from the bonded structure. More specifically, the memory dies that are stacked and to be diced do not need to accommodate TSVs and areas reserved for deployment of TSVs, and each of the memory dies can be devoid of TSVs because each diced memory die can be bonded directly to the logic chip without through another diced memory die. For example, memory banks in a diced memory die can be connected to the logic chip through a redistribution layer (RDL) without through TSVs. By eliminating TSVs and area for routing or connecting TSVs within a memory die, more area and/or space within the memory die can be freed up for other purposes (e.g., deploying additional memory banks or cells). The degraded electrical performance, derivative thermal issues, and increased manufacturing complexity and cost associated with dense and/or long TSVs mentioned above can also be avoided or mitigated in the bonded structure.

U.S. Pat. Nos. 10,636,780 and 10,283,492 disclose laminated interposers and packages with embedded trace-vias and interconnects. By contrast, the present disclosure includes embodiments that stack and bond memory dies to a logic chip such that the memory dies (e.g., memory banks of high bandwidth memory dies, dynamic random access memory (DRAM) dies) can communicate with the logic chip without the use of TSVs. Additionally, memory dies associated with different memory channels in the same memory group and/or memory dies associated with same memory channels from different memory groups can be disposed adjacent to each other, and the memory dies can be connected through conductors (e.g., the conductor 402A, the conductor 404A, the conductor 406A, the conductor 408A, the conductor 402B, the conductor 404B, the conductor 406B, or the conductor 408B) that extend or route under the memory dies such that each memory die can be addressed by the logic chip, without the use of TSVs. Advantageously, memory bandwidth and/or capacity may no longer be constrained by a height of a memory stack. Rather, memory bandwidth and/or capacity may increase by disposing memory dies laterally from each other on a surface of the logic chip so long as an area of the logic chip permits. Additionally, TSVs that traverse vertically across various memory dies in a memory stack to connect the memory dies to the logic chip can be eliminated or removed from the bonded structure. More specifically, the memory dies that are stacked and to be diced do not need to accommodate TSVs and areas reserved for deployment of TSVs, and each of the memory dies can be devoid of TSVs because each diced memory die can be bonded directly to the logic chip without through another diced memory die. For example, memory banks in a diced memory die can be connected to the logic chip through a redistribution layer (RDL) without through TSVs. By eliminating TSVs and area for routing or connecting TSVs within a memory die, more area and/or space within the memory die can be freed up for other purposes (e.g., deploying additional memory banks or cells). The degraded electrical performance, derivative thermal issues, and increased manufacturing complexity and cost associated with dense and/or long TSVs mentioned above can also be avoided or mitigated in the bonded structure.

In some embodiments, each of the diced memory dies (e.g., the memory die 152-1 and the memory die 158-3) can be hybrid bonded to the logic chip 160 through minor surfaces. In other embodiments, each of the diced memory dies can be bonded to the logic chip 160 through minor surfaces using adhesive (e.g., a solder connection). In some embodiments, after being diced from the memory dies 152, 154, 156, and/or 158, a diced memory die (e.g., the memory die 152-1) can be reconstituted before bonded to the logic chip 160.

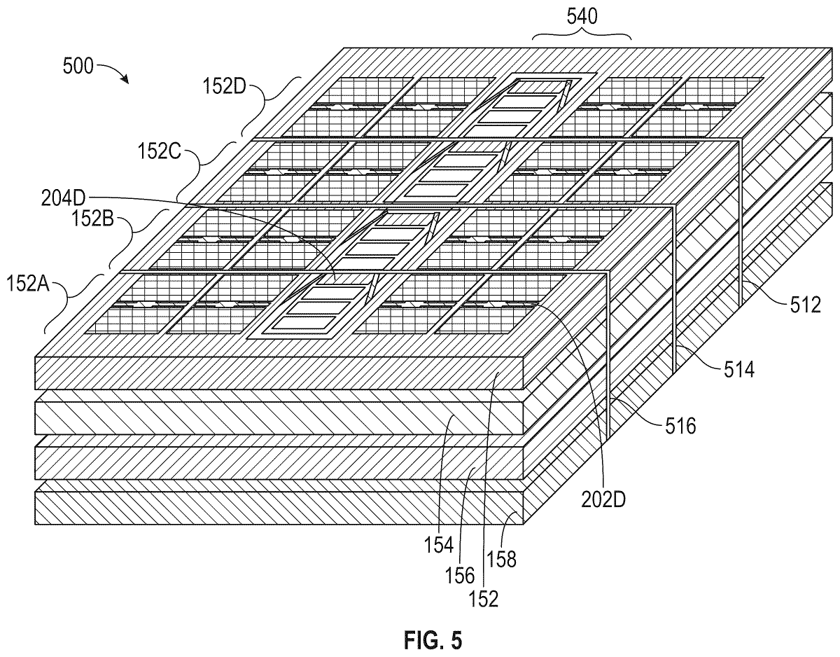

FIG. 5 illustrates a perspective view of an example stacked memory structure 500 including high bandwidth memory dies 158, 156, 154, and 152 to be singulated along a second direction (e.g., a direction along or parallel to the memory channels 152A, 152B, 152C, or 152D) for implementing the memory architecture 100A of FIG. 1A according to some embodiments. Unless otherwise noted, the components of FIG. 5 can be structurally and/or functionally the same as or generally similar to like-numbered components of FIG. 3. As shown in FIG. 3, dicing the stacked memory structure 300 along the singulation streets 316, 314, and 312 can result in forming memory stacks including memory dies having various channels. In contrast to FIG. 3, FIG. 5 shows that the stacked memory structure 500 is to be diced along singulation streets 516, 514, and 512 rather than the singulation streets 316, 314, and 312. Dicing the stacked memory structure 500 along the singulation streets 516, 514, and 512 can result in a memory stack formed to correspond to one memory channel (e.g., different memory stacks correspond to different memory channels).

Similar to FIG. 3, an interconnect region 540 (e.g., a region similar to the interconnect regions 240A, 240B, 240C, or 240D that includes TSVs and/or bypass TSVs) that is not needed or present for the stacked memory structure 500 is nevertheless shown solely for illustrative purpose. In contrast to the interconnect regions 240A, 240B, 240C, and 240D of the bonded structure 200, the interconnect region 540 and the TSVs 204D are not needed for the stacked memory structure 500 and are physically removed or omitted from the stacked memory structure 500 according to embodiments of the present disclosure. In the absence of the interconnect region 540, the electrical connection 202D can still connect, for example, the eight memory banks of the memory channel 152A without the use of TSVs (e.g., the TSV 204D).

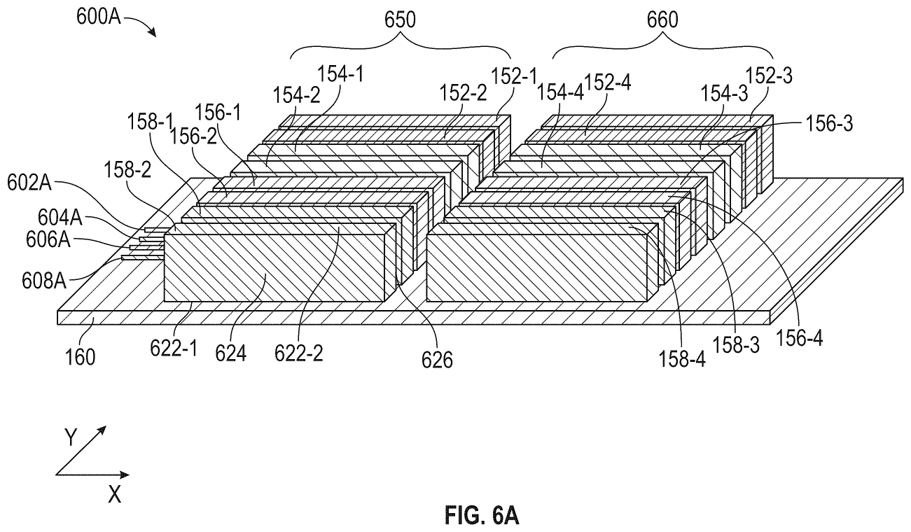

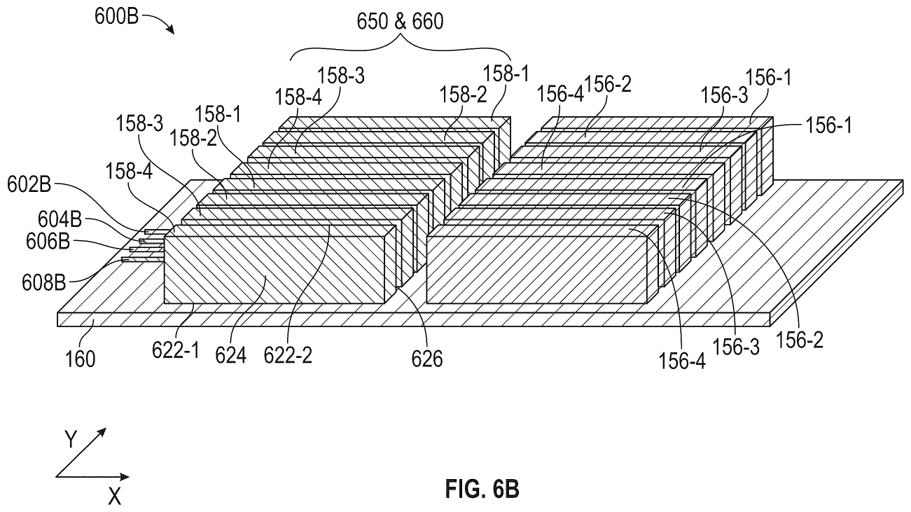

In some embodiments, the stacked memory structure 500 can be singulated (e.g., diced) along the singulation street 516, the singulation street 514, and/or the singulation street 512. For example, after singulating the stacked memory structure 500 along the singulation streets 516, 514, and 512, the memory die 152 can be diced into four memory dies. The four memory dies can be oriented (e.g., vertically flipped or rotated by around ninety degrees) and bonded to the logic chip 160 to form the structure 600A of FIG. 6A or the structure 600B of FIG. 6B.

FIG. 6A illustrates a perspective view of an example bonded structure 600A obtained from singulating, orienting, and/or bonding high bandwidth memory dies 152, 154, 156, and 158 of the stacked memory structure 500 of FIG. 5 according to some embodiments. Unless otherwise noted, the components of FIG. 6A can be structurally and/or functionally the same as or generally similar to like-numbered components of FIG. 4A. A difference between the bonded structure 400A and the bonded structure 600A is that the top major surfaces and the bottom major surfaces (e.g., the top major surface 424 and the bottom major surface 426) extend along the “Y” direction in the bonded structure 400A, whereas the top major surfaces and the bottom major surfaces (e.g., the top major surface 624 or the bottom major surface 626) extend along the “X” direction in the bonded structure 600A. In some embodiments, the structure 600A shows different memory channels in the same memory group or rank are grouped together or disposed adjacent to each other along the “Y” direction.

As shown in FIG. 6A, the bonded structure 600A includes the logic chip 160, a memory group 650, and a memory group 660. The memory group 650 can include a memory die 152-1, a memory die 152-2, a memory die 154-1, a memory die 154-2, a memory die 156-1, a memory die 156-2, a memory die 158-1, and/or a memory die 158-2. The memory group 660 can include a memory die 152-3, a memory die 152-4, a memory die 154-3, a memory die 154-4, a memory die 156-3, a memory die 156-4, a memory die 158-3, and/or a memory die 158-4.

In contrast to the bonded structure 400A where the conductors 402A, 404A, 406A, and/or 408A are routed through or geometrically intersect top major surfaces (e.g., the top major surface 424) and bottom major surfaces (e.g., the bottom major surface 426) of the diced memory dies, the conductors 602A, 604A, 606A, and/or 608A are routed under minor surfaces (e.g., routed in the BEOL layers of the logic chip 160) of the diced memory dies due to the orientations of the diced memory dies. For example, the conductor 608A is routed along a bottom minor surface 622-1 of the memory die 158-2 to electrically connect the memory die 158-2 to the logic chip 160. The bottom minor surface 622-1 can be planarized before hybrid bonded to the logic chip 160. A top minor surface 622-2 of the memory die 158-2 can include artifacts indicative of a singulation process.

In some embodiments, each of the memory banks in a memory die is electrically connected with each other before and after one or more singulation processes are applied. For example, each of the memory banks A1 through A8 in the memory die 158-1 is electrically connected with each other through the electrical connection 202A (shown in FIG. 2A) before the memory die 158-1 is diced from the memory die 158, and after the memory die 158-1 is diced from the memory die 158 and bonded to the logic chip 160 as shown in FIG. 6A. The logic chip 160 can access each of the memory banks Al through A8 in the memory die 158-1 at least through the conductor 608A. For example, the conductor 608A can include at least a conductive trace that is routed in a redistribution layer (RDL), where the conductive trace can electrically connect (e.g., along with the electrical connection 202A) the logic chip 160 to the memory banks A1 through A8. In some embodiments, the RDL can be a RDL of the logic chip 160 or a RDL of the memory die 158-1. A such, memory banks in the memory die 158-1 can be connected to the logic chip 160 at least through the RDL without the use of TSVs.

FIG. 6B illustrates a perspective view of an example bonded structure 600B obtained from singulating, orienting, and/or bonding high bandwidth memory dies 152, 154, 156, and 158 of the stacked memory structure 500 of FIG. 5 according to some embodiments. Unless otherwise noted, the components of FIG. 6B can be structurally and/or functionally the same as or generally similar to like-numbered components of FIG. 4B. A difference between the bonded structure 400B and the bonded structure 600B is that the top major surfaces and the bottom major surfaces (e.g., the top major surface 424 and the bottom major surface 426) extend along the “Y” direction in the bonded structure 400B, whereas the top major surfaces and the bottom major surfaces (e.g., the top major surface 624) extend along the “X” direction in the bonded structure 600B. It should be noted that the diced memory dies 154-1, 154-2, 154-3, 154-4, 152-1, 152-2, 152-3, and 152-4 are not shown in FIG. 6B, but can be disposed to extend along the “X” direction. In some embodiments, the structure 600B shows the same memory channels from different memory groups or ranks are grouped together or disposed adjacent to each other along the “Y” direction.

As shown in FIG. 6B, the bonded structure 600B includes at least the logic chip 160, the memory dies 158-1, the memory dies 158-2, the memory dies 158-3, the memory dies 158-4, the memory dies 156-1, the memory dies 156-2, the memory dies 156-3, and the memory dies 156-4.

In contrast to the bonded structure 600A where memory dies (e.g., the memory dies 152-1, 152-2, 154-1, and 154-2) in the same group (e.g., the memory group 650) or diced from different memory dies (e.g., the memory dies 152, 154, 156, and 158) are physically disposed to be adjacent with each other, memory dies diced from the same memory dies are physically disposed to be adjacent with each other in the bonded structure 600B. For example, memory dies 158-1, 158-2, 158-3, and 158-4 that are diced from the memory dies 158 and correspond to different memory groups (e.g., the memory group 650 and the memory group 660) are disposed adjacent to each other to extend along the “Y” direction in the bonded structure 600B.

In some embodiments, the bonded structure 400A, the bonded structure 400B, the bonded structure 600A, and/or the bonded structure 600B can be formed based on at least some of the following steps. First, memory banks can be formed in one or more memory dies. For example, the memory banks A1 through A8 (shown in FIG. 2A) can be formed in the memory die 158. After forming the memory banks, the one or more memory dies can be optionally stacked vertically to form a memory die stack. For example, the memory dies 152, 154, 156, and 158 can be stacked vertically to form the stacked memory structure 300 shown in FIG. 3. Then, the memory die stack can be diced to form a plurality of memory dies. For example, by dicing the memory dies 158 and the memory dies 156 along the singulation streets 316, 314, and 312, or along the singulation streets 516, 514, and 512, the memory dies 158-1, 158-2, 158-3, and 158-4 can be diced from the memory die 158 while the memory dies 156-1, 156-2, 156-3, and 156-4 can be diced from the memory die 156. The diced memory dies 158-1, 158-2, 158-3, 158-4, 156-1, 156-2, 156-3, and 156-4 can be bonded to a logic chip (e.g., the logic chip 160).

In some embodiments, the diced memory dies can be oriented (e.g., flipped vertically) such that the diced memory dies can be perpendicularly bonded (e.g., bonded to the logic chip through minor surfaces) to the logic chip 160. Bonding between the logic chip 160 and the diced memory dies can be conducted and/or facilitated through hybrid bonding or adhesive.

In some embodiments, prior to bonding the diced memory dies to the logic chip 160, the diced memory dies can be reconstituted. For example, prior to bonding the diced memory dies 158-1, 158-2, 158-3, 158-4, 156-1, 156-2, 156-3, and 156-4 to the logic chip 160, the memory dies 158-1, 158-2, 158-3, 158-4, 156-1, 156-2, 156-3, and/or 156-4 can be reconstituted. For example, at least some of the memory dies can be disposed on a substrate and encapsulated by encapsulant. The encapsulant can be planarized, and RDL can be put on top of the encapsulant or the memory dies. Reconstituting the diced memory dies may optionally include forming RDL in the diced memory dies for electrically connecting the memory banks of the diced memory dies to the logic chip. For example, a first RDL can be formed in the memory dies 158-1, 158-2, 158-3, and 158-4, and a second RDL can be formed in the memory dies 156-1, 156-2, 156-3, and 156-4. The first RDL can electrically connect the memory banks (e.g., the memory banks A1 through A8) of the memory dies 158-1, 158-2, 158-3, and 158-4, and the second RDL can electrically connect the memory banks of the memory dies 156-1, 156-2, 156-3, and 156-4. As such, the logic chip 160 may access the memory banks of the diced memory dies at least through the RDLs. In some embodiments, the reconstitution of the diced memory dies can be optionally performed on a carrier substrate or interposer. In these embodiments, after the diced memory dies are reconstituted, the carrier substrate or the interposer can be removed.

Alternatively, RDLs that are utilized to electrically connect memory banks of diced memory dies and the logic chip can be formed on the logic chip. For example, prior to bonding the diced memory dies to the logic chip 160, a RDL can be formed on the logic chip 160 for connecting the memory banks of the diced memory dies to the logic chip 160. In some embodiments, at least some parts of the conductors 402A, 404A, 406A, 408A, 402B, 404B, 406B, 408B, 602A, 604A, 606A, 608A, 602B, 604B, 606B, and 608B can be routed on the RDLs formed in the logic chip 160 and/or the diced memory dies.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Many organic adhesives lack strong chemical or covalent bonds with either element. In such processes, the connections between the elements are weak and/or readily reversed, such as by reheating.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In one example metal bonding process, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

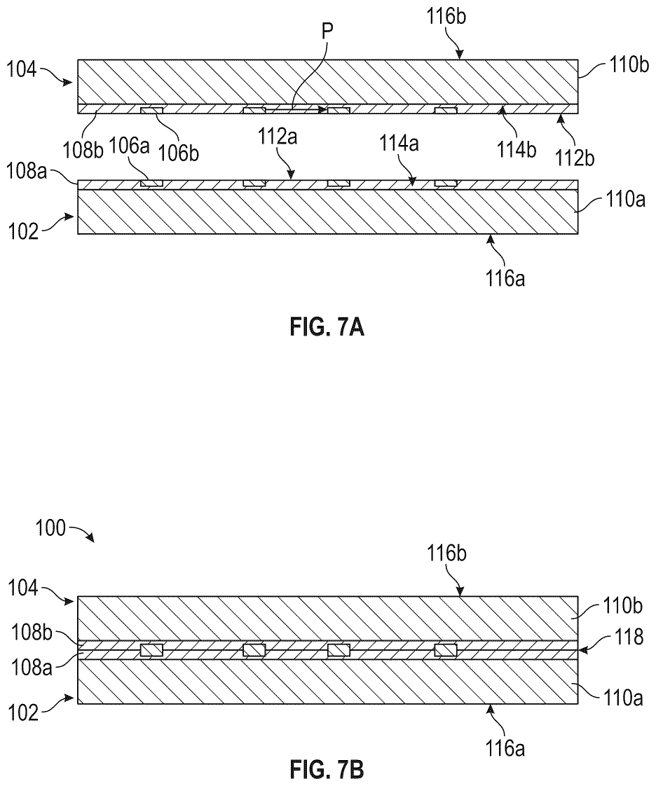

FIGS. 7A and 7B schematically illustrate cross-sectional side views of first and second elements 102, 104 prior to and after, respectively, a process for forming a directly bonded structure, and more particularly a hybrid bonded structure, according to some embodiments. In FIG. 7B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry (not shown) can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, one or both of the elements 102, 104 may not include active circuitry, but may instead comprise dummy elements, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises other materials, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate (e.g., a laminate substrate, a ceramic substrate, etc.) or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding layers for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding surfaces 112a, 112b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially smooths out high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding bonding surfaces, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature. In various embodiments, bonds can form at lower temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 7A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the surface of the feature, and can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded to fair interpretation consistent with this disclosure, the principles and the novel features disclosed herein.

1. A structure comprising:
a logic chip configured to access at least a first plurality of memory dies;
a first conductor; and
the first plurality of memory dies, each of the first plurality of memory dies electrically connected to the logic chip at least through the first conductor,
wherein each of the first plurality of memory dies comprises a first top major surface, a first bottom major surface that is parallel to the first top major surface, and a first top minor surface and a first bottom minor surface non-parallel to the first top major surface and the first bottom major surface, wherein each of the first plurality of memory dies is bonded to the logic chip through the first bottom minor surface.

2. The structure of claim 1, wherein the first top minor surface comprises first artifacts indicative of at least a first singulation process, and wherein an area of the first bottom minor surface is smaller than an area of the first top major surface or smaller than an area of the first bottom major surface.

3. The structure of claim 1, wherein the first plurality of memory dies are diced from a first semiconductor element, and wherein the logic chip accesses the first plurality of memory dies through the first conductor as if the first plurality of memory dies were disposed within and not diced from the first semiconductor element.

4. The structure of claim 1, wherein each of the first plurality of memory dies comprises a first plurality of memory banks.

5. The structure of claim 4, wherein each of the first plurality of memory banks is electrically connected with each other before and after the first plurality of memory dies are diced from a first memory die.

6. The structure of claim 4, wherein at least one of the first plurality of memory banks is electrically unconnected to another of the first plurality of memory banks before the first plurality of memory dies are diced from a first memory die.

7. The structure of claim 4, wherein each of the first plurality of memory banks is electrically connected to the logic chip through a redistribution layer (RDL), and wherein the first conductor comprises a first conductive trace that is routed in the RDL.

8. The structure of claim 4, wherein the first plurality of memory banks comprises two, four, eight, sixteen, thirty-two, or forty-six memory banks, and wherein the first plurality of memory dies comprises four, eight, twelve, or sixteen memory dies.

9. The structure of claim 1, further comprising:
a second conductor; and
a second plurality of memory dies, each of the second plurality of memory dies electrically connected to the logic chip at least through the second conductor,
wherein each of the second plurality of memory dies comprises a second top major surface, a second bottom major surface that is parallel to the second top major surface, and a second top minor surface and a second bottom minor surface non-parallel to the second top major surface and the second bottom major surface, wherein each of the second plurality of memory dies is bonded to the logic chip through the second bottom minor surface, and wherein the second top minor surface comprises second artifacts indicative of at least a second dicing or singulation process.

10. The structure of claim 9, wherein a first memory die and a second memory die are stacked vertically before the first plurality of memory dies are diced from the first memory die and the second plurality of memory dies are diced from the second memory die, and wherein the first plurality of memory dies and the second plurality of memory dies are laterally spaced from each other along a surface of the logic chip after the first plurality of memory dies and the second plurality of memory dies are bonded to the logic chip.

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. A method for forming a bonded structure, the method comprising:
forming at least (i) first memory banks in a first memory die and (ii) second memory banks in a second memory die;
stacking at least the first memory die and the second memory die vertically to form a memory die stack;
dicing the memory die stack to form at least (i) a first plurality of memory dies from the first memory die and (ii) a second plurality of memory dies from the second memory die; and
bonding the first plurality of memory dies and the second plurality of memory dies to a logic chip,
wherein each of the first plurality of memory dies comprises a first plurality of memory banks that correspond to a subset of the first memory banks and each of the second plurality of memory dies comprises a second plurality of memory banks that correspond to a subset of the second memory banks.

26. The method of claim 25, further comprising:
orienting the first plurality of memory dies and the second plurality of memory dies such that the first plurality of memory dies and the second plurality of memory dies are to be perpendicularly bonded to the logic chip.

27. The method of claim 25, wherein bonding the first plurality of memory dies and the second plurality of memory dies comprises bonding each of the first plurality of memory dies and each of the second plurality of memory dies to the logic chip using hybrid bonding.

28. The method of claim 25, further comprising:
reconstituting the first plurality of memory dies and the second plurality of memory dies prior to bonding the first plurality of memory dies and the second plurality of memory dies to the logic chip.

29. The method of claim 28, wherein reconstituting the first plurality of memory dies and the second plurality of memory dies comprises:
forming (i) a first redistribution layer (RDL) in the first plurality of memory dies for electrically connecting the first plurality of memory banks to the logic chip and (ii) a second redistribution layer (RDL) in the second plurality of memory dies for electrically connecting the second plurality of memory banks to the logic chip.

30. The method of claim 29, wherein the first plurality of memory dies and the second plurality of memory dies are carried by a carrier substrate or interposer when being reconstituted.

31. The method of claim 30, further comprising:
removing the carrier substrate after the first plurality of memory dies and the second plurality of memory dies are reconstituted.

32. (canceled)

33. (canceled)

34. (canceled)

35. (canceled)

36. (canceled)

37. (canceled)

38. (canceled)

39. (canceled)

40. (canceled)

41. (canceled)

42. A structure comprising:
a logic chip;
a first conductor; and
a first plurality of integrated circuit dies, each of the first plurality of integrated circuit dies electrically connected to the logic chip at least through the first conductor,
wherein each of the first plurality of integrated circuit dies comprises a top major surface, a bottom major surface that is parallel to the top major surface, and a minor surface non-parallel to the top major surface and the bottom major surface, wherein each of the first plurality of integrated circuit dies is bonded to the logic chip through the minor surface, and wherein the minor surface comprises artifacts indicative of one or more singulation processes.

43. The structure of claim 42, wherein an area of the minor surface is smaller than an area of the top major surface or smaller than an area of the bottom major surface.

44. The structure of claim 42, wherein the first plurality of integrated circuit dies are diced from a first semiconductor element, and wherein the logic chip communicates with the first plurality of integrated circuit dies through the first conductor as if the first plurality of integrated circuit dies were disposed within and not diced from the first semiconductor element.

45. (canceled)

46. (canceled)
